(19) United States
(12) Patent Application Publication
(10) Pub. No.: US 2023/0075662 A1
(43) Pub. Date: Mar. 9, 2023

(54) SEMICONDUCTOR MOUNTING STRUCTURE

(71) Applicant: FUJIFILM Corporation, Tokyo (JP)

(72) Inventor: Kazuya MAYUMI, Saitama-shi (JP)

(73) Assignee: FUJIFILM Corporation, Tokyo (JP)

(21) Appl. No.: 17/820,151

(22) Filed: Aug. 16, 2022

(30) Foreign Application Priority Data
Sep. 3, 2021 (JP) 2021-143956

(51) Int. Cl. H01L 25/18; H01L 23/31; H01L 23/538; H01L 23/00; H01L 23/367

(52) U.S. Cl. CPC H01L 25/18; H01L 23/3107; H01L 23/5386; H01L 23/562; H01L 23/367; H01L 24/16; H01L 24/32; H01L 24/73; H01L 2224/16145; H01L 2224/16225; H01L 2224/32245; H01L 2224/73253

(57) ABSTRACT

Provided is a semiconductor mounting structure capable of suppressing cracks generated in solder and effectively radiating heat of a heat-generated semiconductor. A DRAM package, a SoC board on which the DRAM package is mounted, and a main board on which the SoC board is mounted are provided. A silicon chip is mounted on a surface of the SoC board facing the main board, and the main board has an opening portion at least at a position facing the silicon chip of the SoC board.

### CROSS-REFERENCE TO RELATED APPLICATION

The present application claims priority under 35 U.S.C § 119(a) to Japanese Patent Application No. 2021-143956 filed on Sep. 3, 2021, which is hereby expressly incorporated by reference, in its entirety, into the present application.

### BACKGROUND OF THE INVENTION

### 1. Field of the Invention

The present invention relates to a semiconductor mounting structure, and more particularly, to a semiconductor mounting structure comprising a plurality of semiconductor components and a plurality of boards.

### 2. Description of the Related Art

JP2016-66699A discloses a mounting structure in which a composite wiring board including a first wiring board and a second wiring board is mounted on a third wiring board such as a motherboard. The first wiring board has an opening portion for accommodating electronic components, and the second wiring board has the electronic components mounted on a lower surface thereof.

### SUMMARY OF THE INVENTION

One embodiment according to the technique of the present disclosure provides a semiconductor mounting structure capable of suppressing warping generated in a board and suppressing cracks generated in solder by effectively radiating heat of a heat-generated semiconductor component.

(1) A semiconductor mounting structure comprising: a first semiconductor component; a first board on which the first semiconductor component is mounted; and a second board on which the first board is mounted, wherein a second semiconductor component is mounted on a surface of the first board facing the second board, and the second board has an opening portion at least at a position facing the second semiconductor component of the first board.

(2) The semiconductor mounting structure according to (1), in which the first semiconductor component is a semiconductor package in which a first semiconductor element is sealed with a resin, and the second semiconductor component is a second semiconductor element in which an external terminal is formed on a mounting surface of the second semiconductor component.

(3) The semiconductor mounting structure according to (1) or (2), in which in the first semiconductor component, a peripheral portion of a mounting surface of the first semiconductor component is mounted on the first board, and in the second semiconductor component, a mounting surface of the second semiconductor component is mounted to face the first board, and mounting locations of the first semiconductor component and the second semiconductor component are formed at positions that do not overlap in a longitudinal direction of the first board.

(4) The semiconductor mounting structure according to any one of (1) to (3), in which a width of the first semiconductor component in a longitudinal direction is larger than a width of the second semiconductor component in the longitudinal direction, and a solder pattern of the first board on which the first semiconductor component is mounted is formed outside an outer shape of the second semiconductor component.

(5) The semiconductor mounting structure according to any one of (1) to (4), in which the opening portion of the second board is larger than an outer shape of the second semiconductor component.

(6) The semiconductor mounting structure according to any one of (1) to (5), in which the first board includes a thermal deformation suppressing member having the same material property and dimension as the second semiconductor component on a surface opposite to a surface on which the second semiconductor component is mounted.

(7) The semiconductor mounting structure according to (6), in which the thermal deformation suppressing member is disposed at a position overlapping the second semiconductor component via the first board.

(8) The semiconductor mounting structure according to any one of (1) to (7), in which a thermal conductive member is connected to the second semiconductor component.

(9) The semiconductor mounting structure according to (8), in which the thermal conductive member includes a first thermal conductor connected to the second semiconductor component, and a second thermal conductor having one end connected to the first thermal conductor via the opening portion and the other end disposed outside the second board, and the first thermal conductor is softer than the second thermal conductor.

(10) The semiconductor mounting structure according to (9), in which the other end of the second thermal conductor is connected to a housing disposed outside the second board.

(11) The semiconductor mounting structure according to (9) or (10), in which the second board includes a notched portion communicating with the opening portion, and the second thermal conductor is disposed along the notched portion.

(12) The semiconductor mounting structure according to any one of (1) to (11), in which a third thermal conductor is connected to the first semiconductor component.

(13) The semiconductor mounting structure according to (12), in which the third thermal conductor is connected to a housing.

(14) The semiconductor mounting structure according to any one of (1) to (13), in which the first board has first solder patterns in which solder patterns match each other on both surfaces of the first board.

(15) The semiconductor mounting structure according to (14), in which the second board has at least one second solder pattern.

(16) The semiconductor mounting structure according to (15), in which a plurality of the second solder patterns are provided around the opening portion of the second board.

(17) The semiconductor mounting structure according to (15) or (16), in which an area of the second solder pattern is larger than an area of individual solder forming the first solder pattern.

(18) The semiconductor mounting structure according to any one of (1) to (17), in which the first semiconductor component is a semiconductor memory.

(19) The semiconductor mounting structure according to any one of (1) to (18), in which the first board is a system-on-chip board.

### BRIEF DESCRIPTION OF THE DRAWINGS

FIG. 1 is a cross-sectional view of a main part of a semiconductor mounting structure according to a first embodiment.

FIG. 2 is a cross-sectional view in which the mounting structure shown in FIG. 1 is attached to a housing.

FIG. 3A is a bottom view of a SoC board, and FIG. 3B is a top view of the SoC board.

FIG. 4 is a top view of a main board shown in FIG. 1.

FIG. 5 is a cross-sectional view of a main part showing a mounting structure according to a second embodiment.

FIG. 6 is a top view of a main board used in the mounting structure shown in FIG. 5.

FIG. 7 is a cross-sectional view showing a mounting structure according to a third embodiment.

FIG. 8 is a top view of a main board used in the mounting structure shown in FIG. 7.

FIG. 9A is a bottom view of a SoC board used in a mounting structure according to a fourth embodiment, and FIG. 9B is a top view of the SoC board.

FIG. 10 is a cross-sectional view of a main part showing a mounting structure according to a fifth embodiment.

FIG. 11 is a cross-sectional view in which the mounting structure shown in FIG. 10 is attached to a housing.

FIG. 12A is an explanatory view showing warping generated in the SoC board, and FIG. 12B is an explanatory view showing that the warping of the SoC board is suppressed.

### DESCRIPTION OF THE PREFERRED EMBODIMENTS

Preferred embodiments of the present invention will be described in detail below with reference to the accompanying drawings.

In the present specification, as a first semiconductor component of the present invention, a semiconductor package in which the first semiconductor element is sealed with a resin is exemplified. As the semiconductor package, a DRAM package in which a dynamic random access memory (DRAM), which is the first semiconductor element, is sealed with the resin is exemplified. Further, as a second semiconductor component of the present invention, a second semiconductor element in which an external terminal is formed on a mounting surface of the second semiconductor component is exemplified. As the second semiconductor element, a silicon chip such as a central processing unit (CPU) or a graphics processing unit (GPU) is exemplified.

The first semiconductor element is not limited to the DRAM, and may be, for example, a semiconductor memory such as a random access memory (RAM) or a read only memory (ROM). Further, the second semiconductor element is not limited to the silicon chip as well, and may be another second semiconductor element. Hereinafter, the semiconductor mounting structure according to an embodiment comprising the DRAM package and the silicon chip will be described.

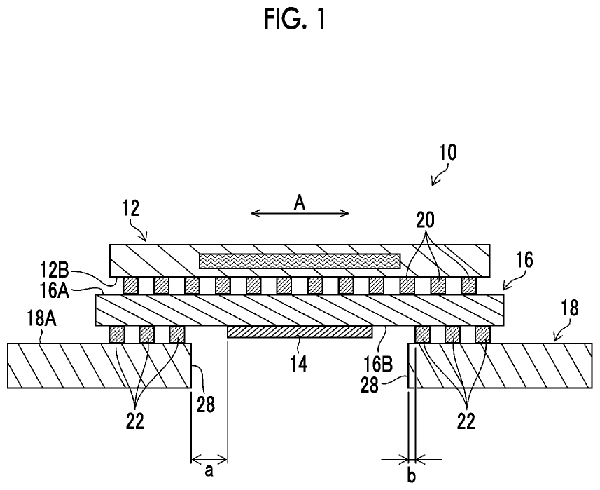

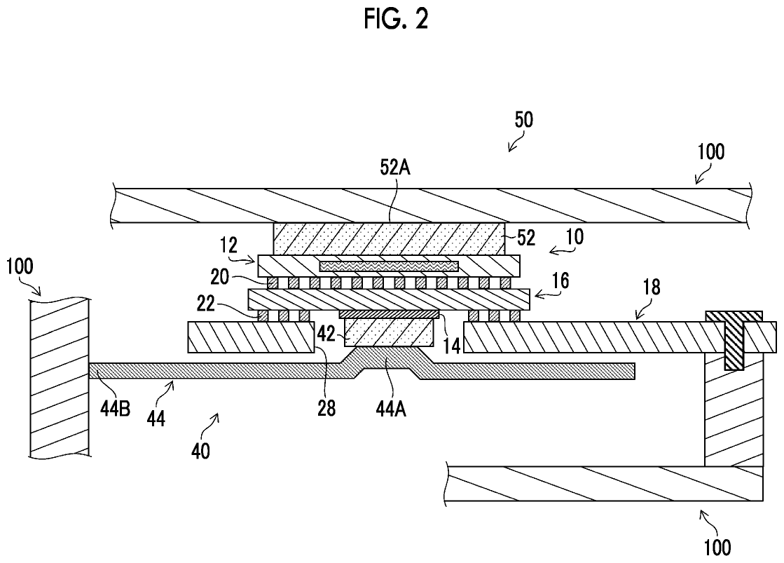

FIG. 1 is a cross-sectional view of a main part showing a configuration of a semiconductor mounting structure (hereinafter, abbreviated as “mounting structure”) 10 according to a first embodiment. Further, FIG. 2 is a cross-sectional view showing a configuration example in a case where the mounting structure 10 shown in FIG. 1 is attached to a housing 100.

As shown in FIGS. 1 and 2, the mounting structure 10 comprises a DRAM package 12, a system-on-chip board (hereinafter, referred to as “system on a chip (SoC) board”) 16 on which the DRAM package 12 is mounted, and a main board 18 on which the SoC board 16 is mounted. Further, a silicon chip 14 is mounted on a surface of the SoC board 16 which faces the main board 18. Here, the SoC board 16 corresponds to a first board of the present invention, and the main board 18 corresponds to a second board of the present invention. Further, for convenience of description, in the DRAM package 12, the SoC board 16, and the main board 18, a surface on an upper side in FIGS. 1 and 2 is referred to as an upper surface, and a surface on a lower side in FIGS. 1 and 2 is referred to as a lower surface.

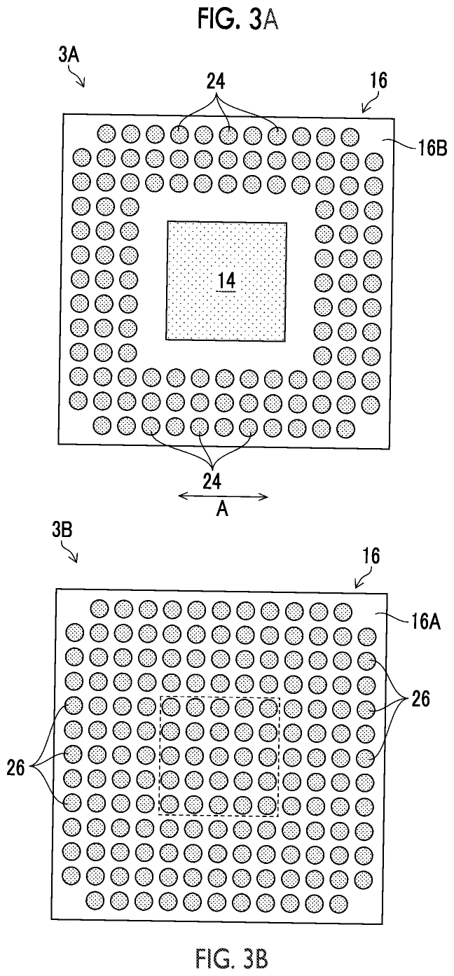

The DRAM package 12 and the SoC board 16 have a plurality of pads (not shown in FIGS. 1 and 2) that are provided on a lower surface 12B of the DRAM package 12 and an upper surface 16A of the SoC board 16 and are electrically connected to each other via solder 20. Similarly, in the SoC board 16 and the main board 18, a plurality of pads (not shown in FIGS. 1 and 2) provided on a lower surface 16B of the SoC board 16 and an upper surface 18A of the main board 18 are electrically connected to each other via the solder 22. According to the mounting structure 10 configured in this way, the mounting structure 10 is configured in a three-layer structure in which the DRAM package 12, the SoC board 16, and the main board 18 are laminated in a vertical direction in FIGS. 1 and 2. Further, the DRAM package 12, the SoC board 16, and the main board 18 are exemplified in a rectangular shape having a longitudinal direction (direction of arrow A in FIGS. 1, 3A, and 3B) in a plan view.

The lower surface 16B of the SoC board 16 is shown in FIG. 3A, and the upper surface 16A of the SoC board 16 is shown in FIG. 3B.

As shown in FIG. 3A, a rectangular silicon chip 14 is mounted on a central portion of the lower surface 16B of the SoC board 16. That is, an upper surface, which is the mounting surface of the silicon chip 14, is mounted facing the SoC board 16. The SoC board 16 is mounted on the main board 18 so that the silicon chip 14 faces the main board 18 (see FIG. 1). Further, on the lower surface 16B of the SoC board 16, a plurality of pads 24 are provided in a grid pattern so as to surround the silicon chip 14 from all sides. The silicon chip 14 becomes a heat generation source in a case where the mounting structure 10 is driven.

As shown in FIG. 3B, a plurality of pads 26 are provided in a grid pattern on the entire upper surface 16A of the SoC board 16. A pad (not shown) of the DRAM package 12 is electrically connected to these pads 26 via solder 20 (see FIG. 1). As a result, a lower surface 12B, which is a mounting surface of the DRAM package 12, is mounted on the upper surface 16A of the SoC board 16. The DRAM package 12 becomes a heat generation source in a case where the mounting structure 10 is driven in the same manner as the silicon chip 14.

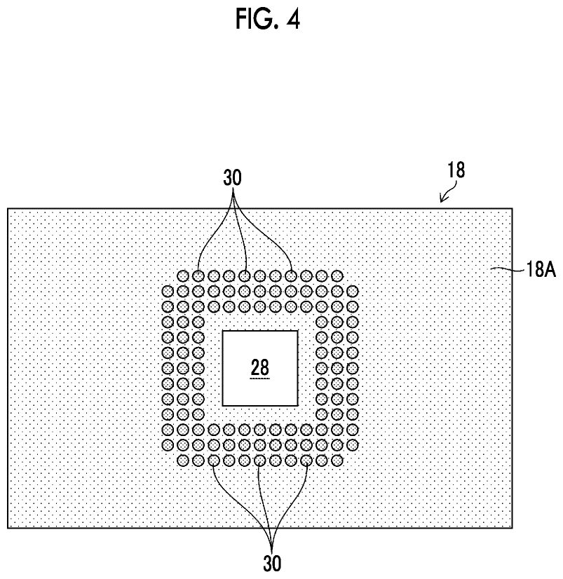

FIG. 4 shows an upper surface 18A of the main board 18.

As shown in FIG. 4, the main board 18 has an opening portion 28 at a position facing the silicon chip 14 of the SoC board 16 (see FIG. 1). The opening portion 28 corresponds to the opening portion of the present invention, and the opening portion 28 is formed at a position facing the silicon chip 14 in a case where the SoC board 16 is mounted on the main board 18. Accordingly, the silicon chip 14 is exposed to the outside through the opening portion 28 in the mounting structure 10. The opening portion 28 functions as an opening portion for radiating the heat generated in the silicon chip 14 to the outside of the mounting structure 10.

Here, in FIGS. 1 and 2, only one opening portion 28 is shown, but the present invention is not limited to this. A plurality of opening portions 28 may be formed on the main board 18. In order to effectively realize the above heat radiation, the opening portion 28 may be provided at least at a position facing the silicon chip 14 of the SoC board 16. Further, it is preferable that the opening portion 28 is larger than an outer shape of the silicon chip 14 in a case where the opening portion 28 is viewed from the side of the DRAM package 12. Accordingly, the heat radiation effect of the silicon chip 14 can be enhanced, and the work of attaching a thermal conductive member (TIM material 42) to be described later to the silicon chip 14 becomes easy.

As shown in FIG. 4, a plurality of pads 30 are provided on the upper surface 18A of the main board 18 in a grid pattern so as to surround the opening portion 28 from all sides, and these pads 30 are respectively connected to the pads 24 of the SoC board 16 (see FIG. 3A) via the solder 22 (see FIG. 1). Accordingly, the SoC board 16 is mounted on the main board 18. The above is the configuration of the mounting structure 10 of the first embodiment.

According to the mounting structure 10 of the first embodiment, the main board 18 has the opening portion 28 at least at a position facing the silicon chip 14 of the SoC board 16 so that the heat of the silicon chip 14 is radiated to the outside of the mounting structure 10 via the opening portion 28. Accordingly, the warping of the DRAM package 12, the SoC board 16, and the main board 18 due to the heat of the silicon chip 14 can be suppressed, and the cracks generated in the solders 20 and 22 can be suppressed.

### Comparison with Comparative Example (Another Configuration Example)

Incidentally, another configuration example for laminating the main board 18, the SoC board 16, and the DRAM package 12 and mounting (connecting) them using the solders is described below. That is, there is a configuration in which the SoC board 16 is mounted on the main board 18, an intermediate board is mounted on the SoC board 16, and the DRAM package 12 is mounted on the intermediate board. In a case of this configuration example, the main board 18, the SoC board 16, the intermediate board, and the DRAM package 12 form a four-layer structure laminated in the vertical direction. In the SoC board 16, the silicon chip 14 is mounted on the upper surface 16A of the SoC board 16 so as to face the intermediate board.

The main board 18, the SoC board 16, and the intermediate board are, for example, boards in which a prepreg sheet and a copper foil are laminated. On the other hand, the DRAM package 12 and the silicon chip 14 are, for example, semiconductor components in which a silicon sheet and a resin sheet are laminated.

Since the above-mentioned board and semiconductor component are formed of materials having different linear expansion coefficients, for example, in a case where the atmospheric temperature rises due to heat generation of the semiconductor component, the dimensions of expansion are different from each other and the warping or undulation occurs in the board or the semiconductor component. Then, there is a problem that a load is locally applied to a part of the solder and cracks occur in the solder.

In the mounting structure 10 of the first embodiment, the SoC board 16 is mounted on the main board 18 so that the silicon chip 14 faces the main board 18, and the DRAM package 12 is directly mounted on the SoC board 16. Accordingly, the configuration without the above-mentioned intermediate board is adopted. According to such a configuration, since the warping or undulation element caused by the intermediate board can be eliminated, the warping or undulation generated in the board or the semiconductor component can be suppressed. According to the mounting structure 10 of the first embodiment, cracks generated in the solder can be suppressed, and thus the above problem can be solved.

The mounting structure 10 has two heat radiating structure portions 40 and 50 shown in FIG. 2, and the mounting structure 10 is attached to the housing 100 via the heat radiating structure portions 40 and 50. Hereinafter, an example of the heat radiating structure portions 40 and 50 will be described.

As shown in FIG. 2, the heat radiating structure portion 40 includes a thermal interface material (TIM) material 42 attached to the silicon chip 14, and a metal member 44 in which one end 44A is connected to the TIM material 42 via the opening portion 28 and the other end 44B is disposed on the outside of the main board 18. Here, the TIM material 42 and the metal member 44 correspond to the thermal conductive member of the present invention. In addition, the TIM material 42 corresponds to a first thermal conductor of the present invention, and the metal member 44 corresponds to a second thermal conductor of the present invention. In the embodiment, a band-shaped sheet metal is used as the metal member 44, but the present invention is not limited to this, and other shapes such as a disk shape may be used.

According to the heat radiating structure portion 40 shown in FIG. 2, the heat generated in the silicon chip 14 by driving the mounting structure 10 is transferred to the TIM material 42, is transferred from the TIM material 42 to the metal member 44, and then is radiated to the outside from an outer surface of the metal member 44. According to the mounting structure 10 having the heat radiating structure portion 40, the heat generated in the silicon chip 14 can be effectively radiated to the outside. Therefore, the warping of the DRAM package 12, the SoC board 16, and the main board 18 due to the heat of the silicon chip 14 can be further suppressed, so that the cracks generated in the solders 22 and 20 can be further suppressed. In addition, since it is possible to suppress the heat transfer of the silicon chip 14 from the SoC board 16 to the DRAM package 12 and the heat transfer of the silicon chip 14 from the SoC board 16 to the main board 18, the DRAM package 12 and the main board 18 can be protected from the heat of the silicon chip 14.

As another configuration example of the heat radiating structure portion 40, a configuration in which one end 44A of the metal member 44 and the silicon chip 14 are directly connected can be considered. In a case where the TIM material 42 is interposed between the one end 44A of the metal member 44 and the silicon chip 14, there is an advantage that the heat of the silicon chip 14 can be effectively radiated. Further, as the TIM material 42, it is preferable to use a member softer than the metal member 44 such as an elastic body having impact absorption and adhesiveness. Accordingly, the load applied to the silicon chip 14 from the metal member 44 at the time of impact can be reduced, and even if a relative positional deviation occurs between the metal member 44 and the silicon chip 14, the TIM material 42 elastically deforms to absorb the positional deviation. As the TIM material 42 in this case, it is preferable to use a gel-like material in which particles having thermal conductivity such as metal powder are added to a resin such as silicon.

In the heat radiating structure portion 40, it is preferable that the other end 44B of the metal member 44 is connected to the housing 100 disposed on the outside of the main board 18. Accordingly, the heat generated in the silicon chip 14 is transferred to the housing 100 via the TIM material 42 and the metal member 44, and is also radiated to the outside air from the housing 100. As a result, the heat generated in the silicon chip 14 can be radiated more effectively. It is preferable that the housing 100 is made of metal having high thermal conductivity, and is made of aluminum as an example.

Next, a heat radiating structure portion 50 shown in FIG. 2 will be described. The heat radiating structure portion 50 has a TIM material 52 attached to the DRAM package 12. The TIM material 52 corresponds to a third thermal conductor of the present invention.

According to the heat radiating structure portion 50, the heat generated in the DRAM package 12 by driving the mounting structure 10 is transferred to the TIM material 52 and is radiated to the outside from the TIM material 52. As a result, according to the mounting structure 10, the heat generated in the DRAM package 12 can be effectively radiated. Therefore, since the heat of the DRAM package 12 can be suppressed from being transferred to the SoC board 16, the silicon chip 14, and the main board 18, the SoC board 16, the silicon chip 14, and the main board 18 can be protected from the heat of the DRAM package 12.

In the heat radiating structure portion 50, it is preferable to connect an upper surface 52A of the TIM material 52 to the housing 100. Accordingly, the heat generated in the DRAM package 12 is transferred to the housing 100 via the TIM material 52, and is also radiated from the housing 100 to the outside air. As a result, the heat generated in the DRAM package 12 can be radiated more effectively. In this example, since the TIM material 52 and the housing 100 are disposed close to each other, the TIM material 52 is directly connected to the housing 100. In a case where the TIM material 52 and the housing 100 are disposed apart from each other, the TIM material 52 and the housing 100 may be connected via the metal member in the same manner as in the heat radiating structure portion 40. Further, as for the TIM material 52, it is preferable to use a gel-like material in which particles having thermal conductivity such as metal powder are added to a resin such as silicon, similarly to the TIM material 42.

As described above, according to the mounting structure 10 of the first embodiment, since it has the heat radiating structure portion 40 for radiating the heat of the silicon chip 14, which is the heat generation source, and the heat radiating structure portion 50 for radiating the heat of the DRAM package 12, which is the heat generation source, the heat generated in the mounting structure 10 can be effectively radiated.

The mounting structure 10 described above has two heat radiating structure portions 40 and 50, but the mounting structure 10 may have at least the heat radiating structure portion 40 among the two heat radiating structure portions 40 and 50. Accordingly, the heat of the silicon chip 14 disposed in the space where it is difficult to radiate heat (a narrow space surrounded by the SoC board 16 and the main board 18) can be effectively radiated. However, by having the heat radiating structure portion 50, the heat generated in the DRAM package 12 can be effectively radiated.

### Other Embodiments

Hereinafter, other embodiments will be described.

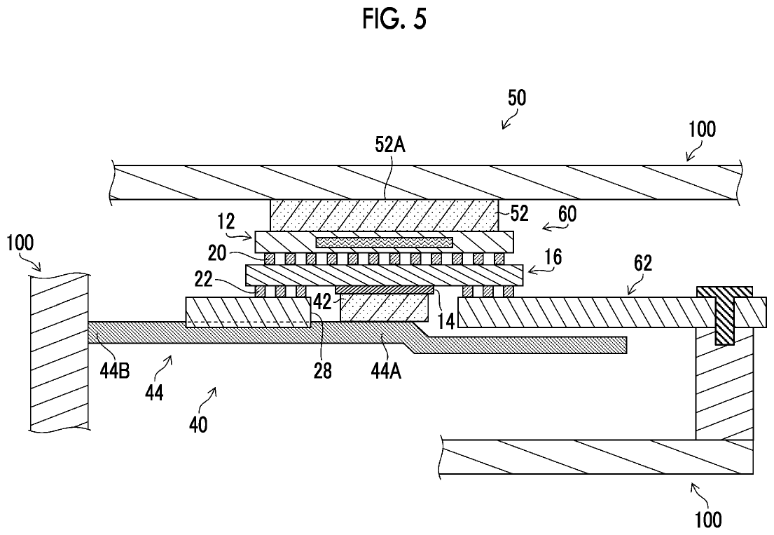

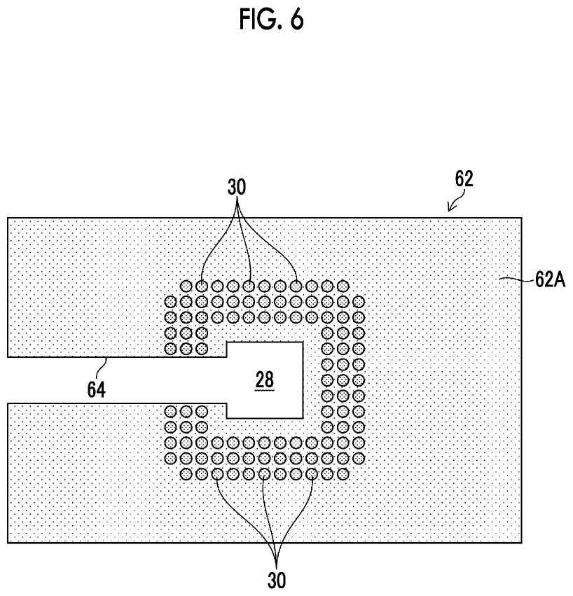

FIG. 5 is a cross-sectional view of a main part showing a mounting structure 60 according to a second embodiment. FIG. 6 is a top view showing an upper surface 62A of a main board 62 used in the mounting structure 60. In explaining the mounting structure 60 shown in FIGS. 5 and 6, members that are the same as or similar to the mounting structure 10 shown in FIGS. 1 to 4 will be denoted by the same reference numerals.

The difference in configuration between the mounting structure 60 and the mounting structure 10 is that the main board 18 of the mounting structure 10 has only the opening portion 28, whereas the main board 62 of the mounting structure 60 has the opening portion 28 and a notched portion 64 communicating with the opening portion 28. The metal member 44 is disposed along the notched portion 64.

As the mounting structure 60, by disposing the metal member 44 along the notched portion 64 of the main board 62, a thickness of the mounting structure 60 including the metal member 44 in the vertical direction can be reduced. That is, the mounting structure 60 including the metal member 44 can be made compact.

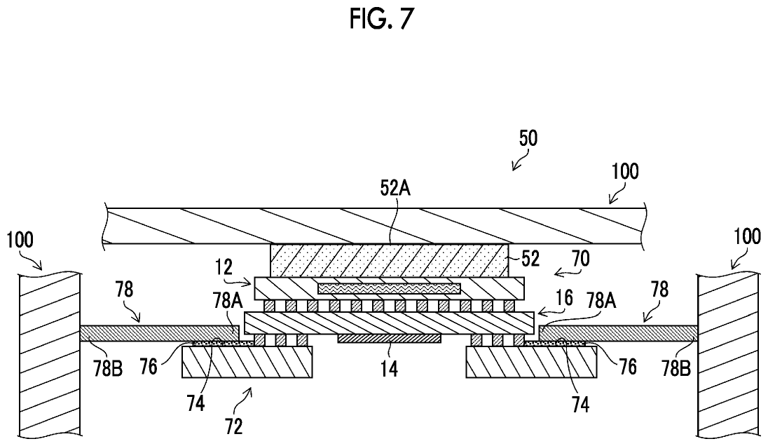

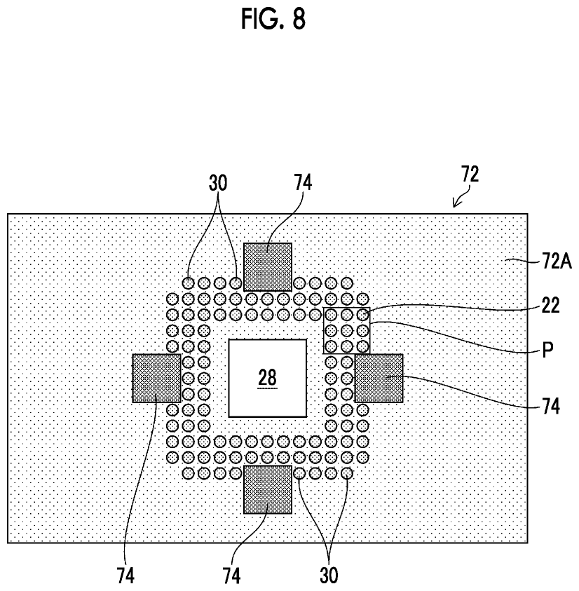

FIG. 7 is a cross-sectional view of a main part showing a mounting structure 70 according to a third embodiment. FIG. 8 is a top view showing an upper surface 72A of a main board 72 used in the mounting structure 70. In explaining the mounting structure 70 shown in FIGS. 7 and 8, members that are the same as or similar to the mounting structure 10 shown in FIGS. 1 to 4 will be denoted by the same reference numerals.

The difference in configuration between the mounting structure 70 and the mounting structure 10 is that the main board 18 of the mounting structure 10 has only the plurality of pads 30, whereas the main board 72 of the mounting structure 70 has the plurality of pads 30 and four solder patterns 74 for heat radiation. These solder patterns 74 are thermally connected to some of the pads 30 among the plurality of pads 30. The solder pattern 74 corresponds to a second solder pattern of the present invention.

For example, the solder pattern 74 is formed in a rectangular shape, and a TIM material 76 shown in FIG. 7 is attached to these solder patterns 74. One end 78A of the metal member 78 is attached to the TIM material 76, and the other end 78B of the metal member 78 is disposed outside the main board 72. The other end 78B is connected to the housing 100. In FIG. 8, although the main board 72 provided with four solder patterns 74 so as to surround the rectangular opening portion 28 is exemplified, the main board 72 may be provided with at least one solder pattern 74.

Since the solder pattern 74 is provided on the main board 72 as in the mounting structure 70, the heat transferred from the silicon chip 14 to the main board 72 can be effectively radiated. Further, by connecting the solder pattern 74 to the metal member 78 via the TIM material 76, the above-mentioned heat can be radiated more effectively. Further, by connecting the other end 78B of the metal member 78 to the housing 100, the above-mentioned heat can be radiated still more effectively. As for the TIM material 76, it is preferable to use a gel-like material in which particles having thermal conductivity such as metal powder are added to a resin such as silicon, similarly to the TIM material 42. Further, although not shown in FIG. 7, it is preferable to comprise the heat radiating structure portion 40 shown in FIG. 2.

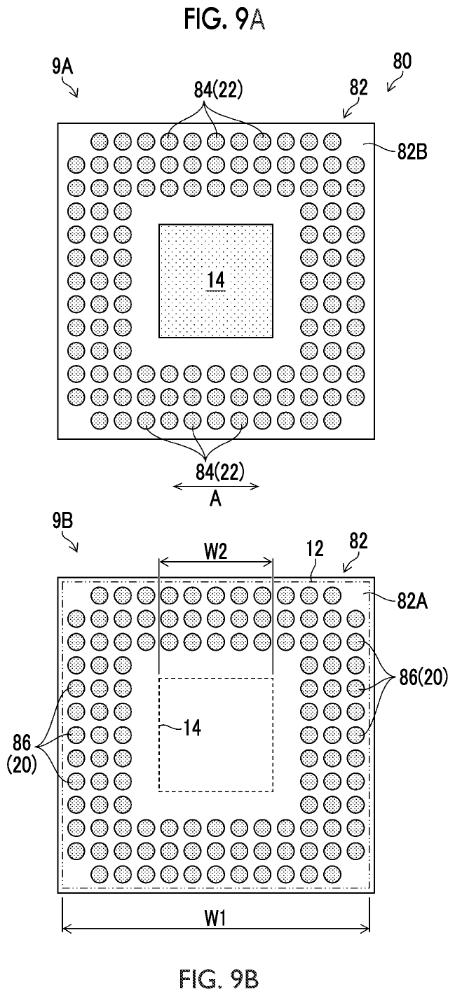

A lower surface 82B of a SoC board 82 used in a mounting structure 80 according to a fourth embodiment is shown in FIG. 9A, and an upper surface 82A of the SoC board 82 is shown in FIG. 9B. In explaining the mounting structure 80 shown in FIGS. 9A and 9B, members that are the same as or similar to the mounting structure 10 shown in FIGS. 1 to 4 will be denoted by the same reference numerals.

The difference in the configuration between the mounting structure 80 and the mounting structure 10 will be described. The SoC board 16 of the mounting structure 10 has a form in which the plurality of pads 24 disposed on the lower surface 16B and the plurality of pads 26 disposed on the upper surface 16A are not disposed on the same axis in the vertical direction. On the other hand, the SoC board 82 of the mounting structure 80 has a form in which a plurality of pads 84 disposed on the lower surface 82B and a plurality of pads 86 disposed on the upper surface 82A are disposed on the same axis in the vertical direction. In FIGS. 9A and 9B, the solders 22 and 20 are shown overlapping the pads 84 and 86, respectively for convenience of explanation.

By disposing the plurality of pads 84 and the plurality of pads 86 of the SoC board 82 on the same axis in the vertical direction as in the mounting structure 80, the load applied to the solders 20 and 22 can be reduced.

Further, according to the mounting structure 80, a peripheral portion of the mounting surface of the DRAM package 12 (lower surface 12B of the DRAM package 12) indicated by a two-dot chain line in FIG. 9B is mounted on the SoC board 82. In the silicon chip 14 shown in FIG. 9A, the mounting surface of the silicon chip 14 (upper surface of the silicon chip 14) is mounted so as to face the SoC board 82. The mounting locations of the DRAM package 12 and the silicon chip 14 are formed at positions that do not overlap in the longitudinal direction of the SoC board 82 indicated by the arrow A.

In this case, according to the mounting structure 80, a width W1 of the DRAM package 12 in the longitudinal direction is larger than a width W2 of the silicon chip 14 in the longitudinal direction, and the solder pattern of the SoC board 82 on which the DRAM package 12 is mounted is formed outside of the outer shape of the silicon chip 14. Here, the above-mentioned solder pattern refers to a disposition pattern of the plurality of solders 20 shown in FIG. 9B. Further, the SoC board 82 has a solder pattern indicating a disposition pattern of the plurality of solders 22 shown in FIG. 9A. That is, the SoC board 82 has first solder patterns of the present invention in which the solder patterns match each other on both surfaces (upper surface 82A and lower surface 82B) of the SoC board 82.

The SoC board 82 is mounted on the main board 72 shown in FIG. 8. For example, the main board 72 has at least one (four in FIG. 8) solder pattern 74. The solder pattern 74 corresponds to a second solder pattern of the present invention. A plurality of the solder patterns 74 are provided around the opening portion 28 of the main board 72. The solder pattern 74 is formed in a rectangular shape as an example, and an area of the solder pattern 74 is larger than an area of the individual solder 22 forming the first solder pattern. For example, the area of the solder pattern 74 is preferably larger than the area of the solder pattern P having three vertical and three horizontal (3×3) solders 22 (see FIG. 8).

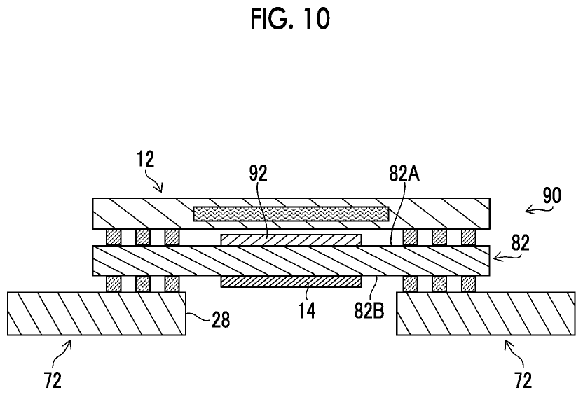

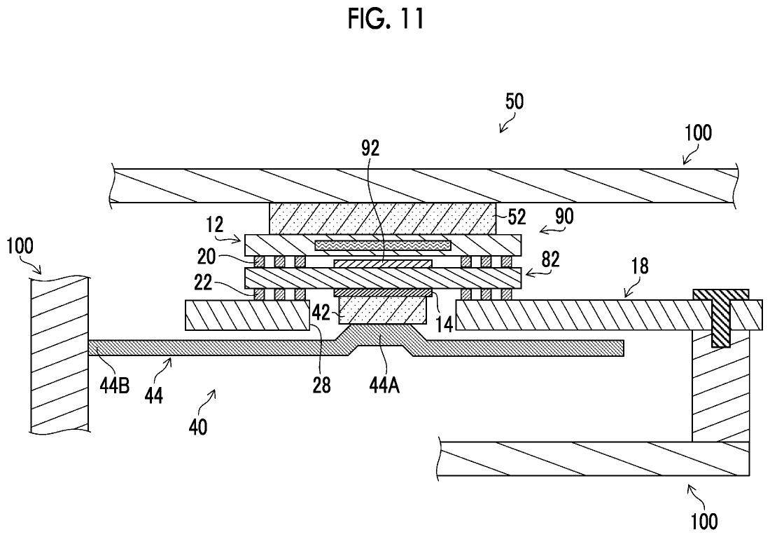

FIG. 10 is a cross-sectional view of a main part showing a mounting structure 90 according to a fifth embodiment. FIG. 11 is a cross-sectional view showing a configuration example in a case where the mounting structure 90 is attached to the housing 100 via the heat radiating structure portions 40 and 50. In explaining the mounting structure 90 shown in FIGS. 10 and 11, members that are the same as or similar to the mounting structures 10, 60, 70, and 80 shown in FIGS. 1 to 9B will be denoted by the same reference numerals.

The difference in configuration between the mounting structure 90 and the mounting structures 10, 60, 70 and 80 is that the SoC board 16 of the mounting structures 10, 60, 70 and 80 has only the silicon chip 14 having electrical performance, whereas the SoC board 82 of the mounting structure 90 has a silicon chip 14 and a pseudo-rectangular silicon chip 92 with respect to the silicon chip 14. The silicon chip 92 is disposed on the upper surface 82A of the SoC board 82. The silicon chip 92 corresponds to a thermal deformation suppressing member of the present invention.

The silicon chip 92 has the same material properties (linear expansion coefficient, Young's modulus, Poisson's ratio) and dimensions as the silicon chip 14, but may not have electrical performance. Regarding the linear expansion coefficient, the difference from the silicon chip 14 is preferably within ±10%, regarding the Young's modulus, the difference from the silicon chip 14 is preferably within ±10%, and regarding the Poisson's ratio, the difference from the silicon chip 14 is preferably within ±20%. Further, regarding the length of one side, which is one element of the dimensions, the difference from the silicon chip 14 is preferably within ±10%. Further, regarding the thickness, which is one element of the dimensions, it is preferable that the thickness is, for example, 0.05 mm or more thinner than the thickness of the solder 20 so as not to come into contact with the DRAM package 12. The silicon chip 92 is mounted on the SoC board 82 by the same method as that of the silicon chip 14. For example, in a case where the silicon chip 14 is mounted by applying an adhesive, the silicon chip 92 is also mounted on the SoC board 82 by applying the adhesive.

In a case where the silicon chip 92 is viewed from the side of the DRAM package 12, it is preferable that the silicon chip 92 is disposed at a position where it overlaps the silicon chip 14. Accordingly, the warping of the SoC board 82 generated due to the heat of the silicon chip 14 can be effectively suppressed.

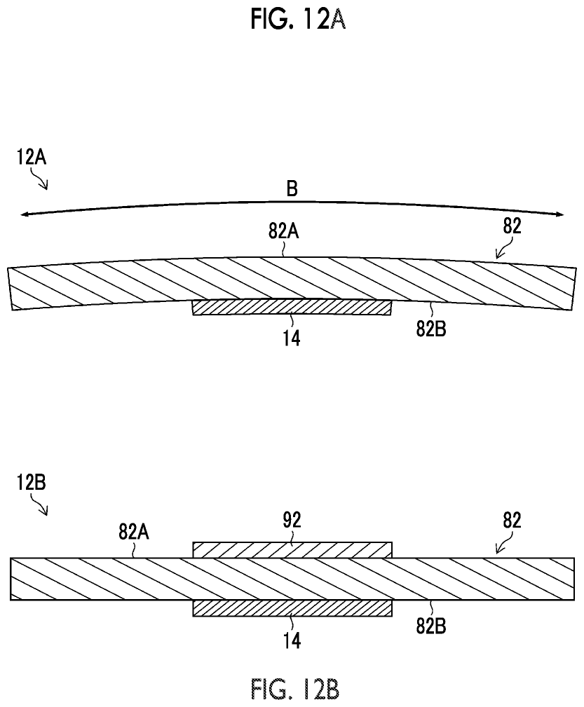

Hereinafter, the warping of the SoC board 82 generated due to the heat of the silicon chip 14 will be described with reference to FIGS. 12A and 12B.

In a case where the silicon chip 14 having electrical performance is mounted on the lower surface 82B of the SoC board 82 in a case where the mounting structure 90 is heated at a high temperature, the silicon chip 14 is difficult to stretch and the SoC board 82, which is a resin board, is easily stretchable because of its property. Accordingly, the SoC board 82 as a whole warps so that a side of the upper surface 82A is convex (a side of the lower surface 82B is concave) as shown by the arrow B of FIG. 12A.

In a case where the silicon chip 92, which is a pseudo-silicon, is mounted on the upper surface 82A of the SoC board 82, the linear expansion coefficients of the side of the upper surface 82A and the side of the lower surface 82B the SoC board 82 are even as shown in FIG. 12B, so that the SoC board 82 is less likely to warp. Accordingly, damage (cracking) of the solders 20 and 22 caused by the warping of the SoC board 82 can be suppressed.

In the above-mentioned mounting structure 90, it is preferable to use the main board 62 having the notched portion 64 shown in FIG. 6, and it is also preferable to use the main board 72 having the solder pattern 74 shown in FIGS. 7 and 8.

Others

Although not shown in the figure, as another embodiment, in a case where the DRAM package 12 and the silicon chip 14 are viewed from above and below, it is preferable that the positions, the numbers, and the shapes of the silicon sheet of the DRAM package 12 and the silicon sheet of the silicon chip 14 are substantially matched each other. Accordingly, in a case where the atmospheric temperature changes, the load applied to the solders 20 and 22 can be reduced.

Further, as shown in FIG. 1, a distance a between an end portion of the opening portion 28 and an end portion of the silicon chip 14 in the horizontal direction is preferably, for example, 1 mm or more from the viewpoint of easily attaching the TIM material 42 (see FIG. 2) to the silicon chip 14. Further, a distance b between the end portion of the opening portion 28 and the outer peripheral surface of the solder 22 is preferably 0.5 mm or more from the viewpoint of effectively disposing the pad 30 on the main board 18.

The mounting structure according to the embodiment has been described above, but the present invention may include further improvements or modifications without departing from the scope of the present invention.

### EXPLANATION OF REFERENCES

10: mounting structure
12: DRAM package
12B: lower surface
14: silicon chip
16: SoC board
16A: upper surface
16B: lower surface
18: main board
18A: upper surface
20: solder
22: solder
24: pad
26: pad
28: opening portion
30: pad
40: heat radiating structure portion
42: TIM material
44: metal member
44A: one end
44B: other end
50: heat radiating structure portion
52: TIM material
52A: upper surface
60: mounting structure
62: main board
62A: upper surface
64: notched portion
70: mounting structure
72: main board
72A: upper surface
74: solder pattern
76: TIM material
78: metal member
78A: one end
78B: other end
80: mounting structure
82: SoC board
82A: upper surface
82B: lower surface
84: pad
86: pad
90: mounting structure
92: silicon chip

What is claimed is:

1. A semiconductor mounting structure comprising:
a first semiconductor component;
a first board on which the first semiconductor component is mounted; and
a second board on which the first board is mounted,
wherein a second semiconductor component is mounted on a surface of the first board facing the second board, and
the second board has an opening portion at least at a position facing the second semiconductor component of the first board.

2. The semiconductor mounting structure according to claim 1,
wherein the first semiconductor component is a semiconductor package in which a first semiconductor element is sealed with a resin, and the second semiconductor component is a second semiconductor element in which an external terminal is formed on a mounting surface of the second semiconductor component.

3. The semiconductor mounting structure according to claim 1,
wherein in the first semiconductor component, a peripheral portion of a mounting surface of the first semiconductor component is mounted on the first board, and in the second semiconductor component, a mounting surface of the second semiconductor component is mounted to face the first board, and
mounting locations of the first semiconductor component and the second semiconductor component are formed at positions that do not overlap in a longitudinal direction of the first board.

4. The semiconductor mounting structure according to claim 1,
wherein a width of the first semiconductor component in a longitudinal direction is larger than a width of the second semiconductor component in the longitudinal direction, and a solder pattern of the first board on which the first semiconductor component is mounted is formed outside an outer shape of the second semiconductor component.

5. The semiconductor mounting structure according to claim 1,
wherein the opening portion of the second board is larger than an outer shape of the second semiconductor component.

6. The semiconductor mounting structure according to claim 1,
wherein the first board includes a thermal deformation suppressing member having the same material property and dimension as the second semiconductor component on a surface opposite to a surface on which the second semiconductor component is mounted.

7. The semiconductor mounting structure according to claim 6,
wherein the thermal deformation suppressing member is disposed at a position overlapping the second semiconductor component via the first board.

8. The semiconductor mounting structure according to claim 1,
wherein a thermal conductive member is connected to the second semiconductor component.

9. The semiconductor mounting structure according to claim 8,
wherein the thermal conductive member includes
a first thermal conductor connected to the second semiconductor component, and
a second thermal conductor having one end connected to the first thermal conductor via the opening portion and the other end disposed outside the second board, and
the first thermal conductor is softer than the second thermal conductor.

10. The semiconductor mounting structure according to claim 9,
wherein the other end of the second thermal conductor is connected to a housing disposed outside the second board.

11. The semiconductor mounting structure according to claim 9,
wherein the second board includes a notched portion communicating with the opening portion, and
the second thermal conductor is disposed along the notched portion.

12. The semiconductor mounting structure according to claim 1,
wherein a third thermal conductor is connected to the first semiconductor component.

13. The semiconductor mounting structure according to claim 12,
wherein the third thermal conductor is connected to a housing.

14. The semiconductor mounting structure according to claim 1,
wherein the first board has first solder patterns in which solder patterns match each other on both surfaces of the first board.

15. The semiconductor mounting structure according to claim 14,
wherein the second board has at least one second solder pattern.

16. The semiconductor mounting structure according to claim 15,
wherein a plurality of the second solder patterns are provided around the opening portion of the second board.

17. The semiconductor mounting structure according to claim 15,
wherein an area of the second solder pattern is larger than an area of individual solder forming the first solder pattern.

18. The semiconductor mounting structure according to claim 1,
wherein the first semiconductor component is a semiconductor memory.

19. The semiconductor mounting structure according to claim 1,
wherein the first board is a system-on-chip board.
